(19) United States
(12) Patent Application Publication
(10) Pub. No.: US 2024/0370361 A1
(43) Pub. Date: Nov. 7, 2024

(54) COMMON DATA STROBE AMONG MULTIPLE MEMORY DEVICES

(71) Applicant: Rambus Inc., San Jose, CA (US)

(72) Inventors: Joohee KIM, Sunnyvale, CA (US); Dongyun LEE, Sunnyvale, CA (US); Steven C. WOO, Saratoga, CA (US)

(21) Appl. No.: 18/687,116

(22) PCT Filed: Aug. 23, 2022
(86) PCT No.: PCT/US22/41200

§ 371 Date: Feb. 27, 2024

Related U.S. Application Data
(60) Provisional application No. 63/241,171, filed on Sep. 7, 2021.
(60) Provisional application No. 63/279,838, filed on Nov. 16, 2021.

(51) Int. Cl. G06F 12/02

(52) U.S. Cl. CPC G06F 12/0223

(57) ABSTRACT

Multiple (e.g., four) memory devices on a module are connected to a common pair of differential data strobe signal conductors. The common pair of differential data strobe conductors are also coupled to a memory controller to time the transmission of data to the multiple memory devices and to time the reception of data from the memory devices. The controller calibrates two or more different data transmission delays relative to its transmission of a write data strobe signal on the common pair of differential data strobe conductors. The controller also calibrates to account for two or more different data reception delays (skew) relative to its reception of a read data strobe signal on the common pair of differential data strobe conductors.

### BRIEF DESCRIPTION OF THE DRAWINGS

FIG. 1 is a block diagram illustrating a memory system.

FIG. 2 is a schematic diagram illustrating the electrical environment of a common data strobe connected to multiple devices.

FIG. 3 is a block diagram illustrating write data strobe calibration circuitry.

FIG. 4 is a block diagram illustrating read data strobe calibration circuitry.

FIG. 5 is a flowchart illustrating a method of sharing data strobe signals.

FIG. 6 is a flowchart illustrating a method of providing a read data strobe.

FIG. 7 is a flowchart illustrating a method of transmitting data to multiple memory devices using a common write data strobe.

FIG. 8 is a block diagram of a processing system.

### DETAILED DESCRIPTION OF THE EMBODIMENTS

In an embodiment, multiple (e.g., four) memory devices on a module are connected to a common pair of differential data strobe signal conductors. The common pair of differential data strobe conductors are also coupled to a memory controller to time the transmission of data to the multiple memory devices and to time the reception of data from the memory devices. The controller calibrates two or more different data transmission delays relative to its transmission of a write data strobe signal on the common pair of differential data strobe conductors. The controller also calibrates to account for two or more different data reception delays (skew) relative to its reception of a read data strobe signal on the common pair of differential data strobe conductors.

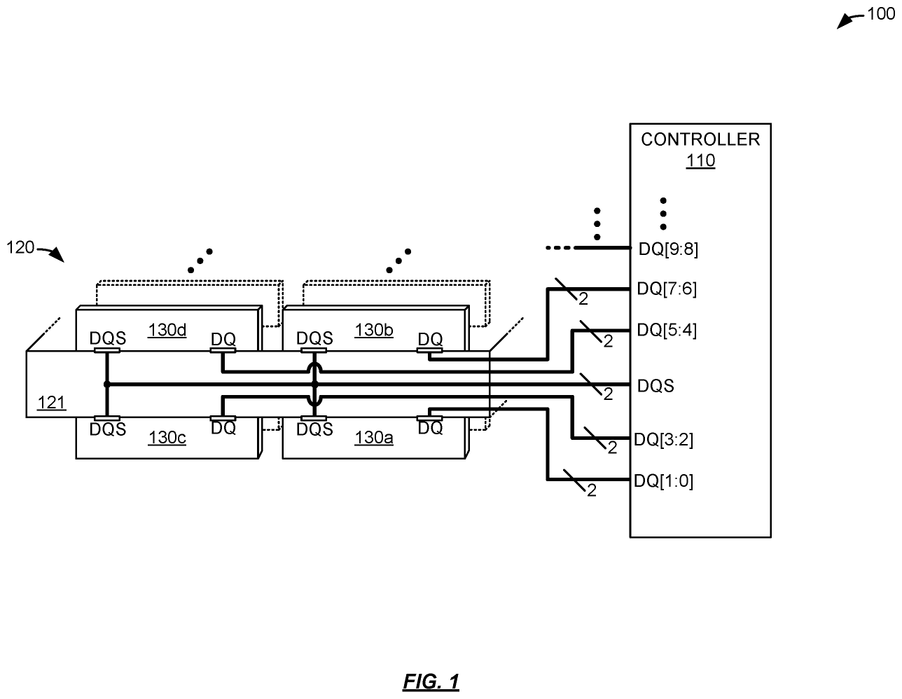

FIG. 1 is a block diagram illustrating a memory system. In FIG. 1, memory system 100 comprises controller 110 and module 120. Module 120 includes substrate 121, and memory devices 130a-130d. Module 120 may include additional memory devices, data buffer devices, and/or a registered clock driver (RCD) device that are not shown in FIG. 1. Memory device 130a and memory device 130c are disposed on a first (e.g., bottom, in FIG. 1) side of substrate 121. Memory device 130b and memory device 130d are disposed on a second (e.g., top, in FIG. 1) side of substrate 121. In an embodiment, memory devices 130a-130d are dynamic random access memory (DRAM) devices.

Controller 110 is operatively coupled to module 120 via data (DQ) signals and at least one data strobe signal DQS. In an embodiment, data strobe signal DQS uses differential signaling and is carried using two signal conductors. DQ signals use single ended signaling and are each carried using a single signal conductor. In FIG. 1, data strobe signal DQS is operatively coupled to each memory device 130a-130d. Data signals DQ [1:0] to/from controller 110 are operatively coupled to memory device 130a. Data signals DQ [3:2] to/from controller 110 are operatively coupled to memory device 130c. Data signals DQ [5:4] to/from controller 110 are operatively coupled to memory device 130d. Data signals DQ [7:6] to/from controller 110 are operatively coupled to memory device 130b. Additional data signals (e.g., DQ [9:8], or DQ [19:8]) to/from controller 110 may be operatively coupled to additional memory devices not shown in FIG. 1.

As illustrated, module 120 may be considered to be an unbuffered module. This, however, is merely one example of the types of module that may include memory devices 130a-130d. Other examples of modules include dual inline memory module (DIMM) such as DDR4, DDR5 etc. DIMM, load reduced DIMM (LRDIMM), registered DIMM (RDIMM), fully buffered DIMM (FB-DIMM), unbuffered DIMM (UDIMM), or SO-DIMM.

In an embodiment, controller 110, and memory devices 130a-130d are integrated circuit type devices, such as are commonly referred to as “chips”. The controller functionality of a memory controller (such as the controller functionality of controller 110) manages the flow of data going to and from memory devices and/or memory modules. Memory devices 130a-130d may be standalone devices, or may include multiple memory integrated circuit dies-such as components of a multi-chip module. A memory controller can be a separate, standalone chip, or integrated into another chip. For example, a memory controller may be included on a single die with a microprocessor, or included as part of a more complex integrated circuit system such as a block of a system on a chip (SOC).

To time the reception of data DQ [7:0] by memory devices 130a-130d, controller 110 transmits, accompanying the data DQ [7:0], a write data strobe signal DQS that is common to memory devices 130a-130d. To time the reception of data DQ [7:0] by controller 110, a single one of memory devices 130a-130d transmits, accompanying the data DQ [7:0], a data strobe signal DQS to be used by controller 110 as a common read data strobe for memory devices 130a-130d.

Because memory devices 130a-130d may have different delays from controller 110 to a respective memory device 130a-130d, controller 110 may transmit different groups of data DQ [7:0] at different times (i.e., different delays) relative to the transmitted write data strobe signal DQS accompanying the data DQ [7:0]. Thus, for example, controller 110 may be configured (or calibrated) to transmit data signals DQ [1:0] and data signal DQ [7:6] to memory devices 130a-130b, respectively with a first delay relative to the DQS signal and also configured (or calibrated) to transmit data signals DQ [3:2] and data signal DQ [5:4] to memory devices 130c-130d, respectively with a second delay relative to the DQS signal that is not equal to the first delay. In an embodiment, for the DQS signal, memory devices 130a-130b have less delay from controller 110 to memory devices 130a-130b relative to the DQS signal than the delay relative to the DQS signal from controller 110 to memory devices 130c-130d and the first delay is less than the second delay.

Because memory devices 130a-130d may have different delays from a respective memory device 130a-130d to controller 110, controller 110 may receive different groups of data DQ [7:0] at different times (i.e., different delays) relative to the received read data strobe signal DQS accompanying the data DQ [7:0]. Thus, for example, controller 110 may be configured (or calibrated) to time the sampling of data signals DQ [1:0] and data signal DQ [7:6] from memory devices 130a-130b, respectively using a first delay relative to a received read data strobe on DQS and also configured (or calibrated) to time the sampling of data signals DQ [3:2] and data signal DQ [5:4] from memory devices 130c-130d, respectively using a second delay that is not equal to the first delay.

In an embodiment, using delay locked loops timed to a clock signal (not shown in FIG. 1), memory devices 130a-130d may be configured to operate in lockstep and thereby transmit their respective bits of data DQ [7:0] at substantially the same time. Further, a single one of memory devices 130a-130d (e.g., memory device 130d) may be configured to transmit a DQS on behalf of all memory devices 130a-130d. Thus, in this embodiment, for example, there may be a first delay on DQ [7:6] and DQ [1:0] from memory devices 130a-130b to controller 110 and a second delay on DQ [3:2] and DQ [5:4] from memory devices 130c-130d, respectively, where the first delay and the second delay are not equal. In this example, controller 110 would sample DQ [7:6] and DQ [1:0] and DQ [3:2] and DQ [5:4] at different delays relative to the DQS signal received from one of the memory devices 130a-130d (e.g., memory device 130d) transmitting the DQS signal on behalf of all of memory devices 130a-130d.

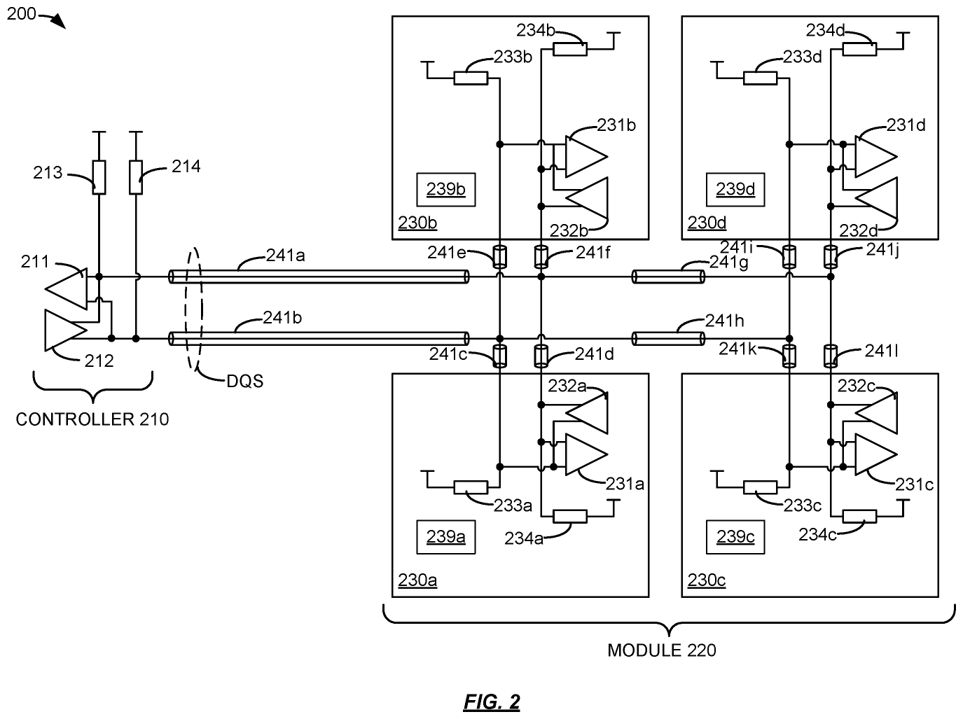

FIG. 2 is a schematic diagram illustrating the electrical environment of a common data strobe connected to multiple devices. FIG. 2 illustrates, for example, an electrical signaling environment 200 similar to the DQS signal connections between controller 110 and memory devices 130a-130d illustrated in FIG. 1.

In FIG. 2, a controller 210 is illustrated having a DQS receiver 211, DQS transmitter 212, and DQS termination impedances 213-214. A module 220 is illustrated with four memory devices 230a-230d. Each memory device 230a-230d, respectively, includes a DQS receiver 231a-231d, a DQS transmitter 232a-232d, DQS termination impedance 233a-233d, DQS termination impedance 234a-234d, and a configuration 239a-239d (e.g., configuration information in storage such as a register). Interconnect 241a-241l connects the controller DQS receiver 211 and controller DQS transmitter 212 to the DQS receivers 231a-231d and DQS transmitters 232a-232d of memory devices 230a-230d. In an embodiment, interconnect 241a-241l may be configured in an H-tree routing topology. In an embodiment, interconnect 241a-241l may be configured in a star signal routing topology (not shown in FIG. 2).

In particular, interconnect 241a-241b runs from controller DQS receiver 211 and controller DQS transmitter 212 to junctions with interconnect 241f and 241d, and interconnect 241c and 241e, respectively. From these junctions, interconnect 241g-241h run to junctions with interconnect 241j and 241l, and interconnect 241i and 241k, respectively. Interconnect 241a-241b may represent, in aggregate, signal conductors on the package of the controller, printed circuit board traces (e.g., motherboard signal conductors), module connector connection, and a first section of module circuit board trace. Interconnect 241c-241f may represent module circuit board vias that connect interconnect 241a-241b to memory devices 230a-230b. Interconnect 241g-241h may represent a second section of module circuit board traces. Interconnect 241i-241l may represent module circuit board vias that connect interconnect 241g-241h to memory devices 230c-230d.

In an embodiment, controller DQS termination impedances 213-214 and memory device DQS termination impedances 233a-233d 234a-234d are configured with different impedance values depending upon whether the controller 210 is performing a write (i.e., driving DQS) or is performing a read (i.e., receiving DQS) of memory devices 230a-230d. When the controller 210 is performing a write, controller DQS termination impedances 213-214 are disconnected (i.e., very high impedance) from interconnect 241a-241l. Also, when the controller 210 is performing a write, DQS termination impedances 233a-233d 234a-234d of memory devices 230a-230d are configured present (i.e., have) a selected termination impedance (e.g., a selected on of 34Ω, 40Ω, 48Ω, 60Ω, 80Ω, 120Ω, or 240Ω—as determined by configurations 239a-239d).

When the controller 210 is performing a read, controller DQS termination impedances 213-214 are configured to present (i.e., have) a selected termination impedance (e.g., 5052) to interconnect 241a-241l. Also, when the controller 210 is performing a read, DQS termination impedances 233a-233d 234a-234d of memory devices 230a-230d are configured to either be disconnected, or to present (i.e., have) a selected termination impedance (e.g., a selected one of 34Ω, 40Ω, 48Ω, 60Ω, 80Ω, 120Ω, or 240Ω—as determined by configurations 239a-239d) to interconnect 241a-241l. In particular, in an embodiment, one of the memory devices 230a-230d that is transmitting the DQS signal (e.g., memory device 230d) to controller 210 may be configured to disconnect its DQS termination impedances (e.g., DQS termination impedances 233d-234d) from interconnect 241a-241l and the other memory devices (e.g., memory devices 230a-230c) are configured to present (i.e., have) a selected termination impedance (e.g., a selected one of 34Ω, 40Ω, 48Ω, 60Ω, 80Ω, 120Ω, or 240Ω—as determined by configurations 239a-239c) to interconnect 241a-241l. Table 1 and Table 2 illustrate example termination configurations that may be used when memory device 230d is configured to transmit the DQS signal to the controller on behalf of memory devices 230a-230d. In Table 1 and Table 2, OFF refers to the configuration where the associated memory device DQS termination impedances 233a-233d 234a-234d are configured to be disconnected from interconnect 241a-241l, and RTERM refers to the configured termination impedance.

TABLE 1

| | | DQS | DQS | DQS | DQS |
|---|---|---|---|---|---|
| | Device | termination | termination | termination | termination |
| | transmitting | impedance | impedance | impedance | impedance |
| mode/operation | DQS | 233d-234d | 233c-234c | 233b-234b | 233a-234a |
| read | Memory | OFF | RTERM | RTERM | RTERM |
| | device | | | | |
| | 230d | | | | |
| | Memory | RTERM | OFF | RTERM | RTERM |
| | device | | | | |
| | 230c | | | | |
| | Memory | RTERM | RTERM | OFF | RTERM |
| | device | | | | |
| | 230b | | | | |
| | Memory | RTERM | RTERM | RTERM | OFF |
| | device | | | | |
| | 230a | | | | |
| write | controller | RTERM | RTERM | RTERM | RTERM |

TABLE 2

| | | DQS | DQS | DQS | DQS |
|---|---|---|---|---|---|
| | Device | termination | termination | termination | termination |
| | transmitting | impedance | impedance | impedance | impedance |
| mode/operation | DQS | 233d-234d | 233c-234c | 233b-234b | 233a-234a |
| read | Memory | OFF | OFF | RTERM | RTERM |
| | device | | | | |
| | 230d | | | | |
| | Memory | OFF | OFF | RTERM | RTERM |
| | device | | | | |
| | 230c | | | | |
| | Memory | RTERM | RTERM | OFF | OFF |
| | device | | | | |
| | 230b | | | | |
| | Memory | RTERM | RTERM | OFF | OFF |
| | device | | | | |
| | 230a | | | | |
| write | controller | RTERM | RTERM | RTERM | RTERM |

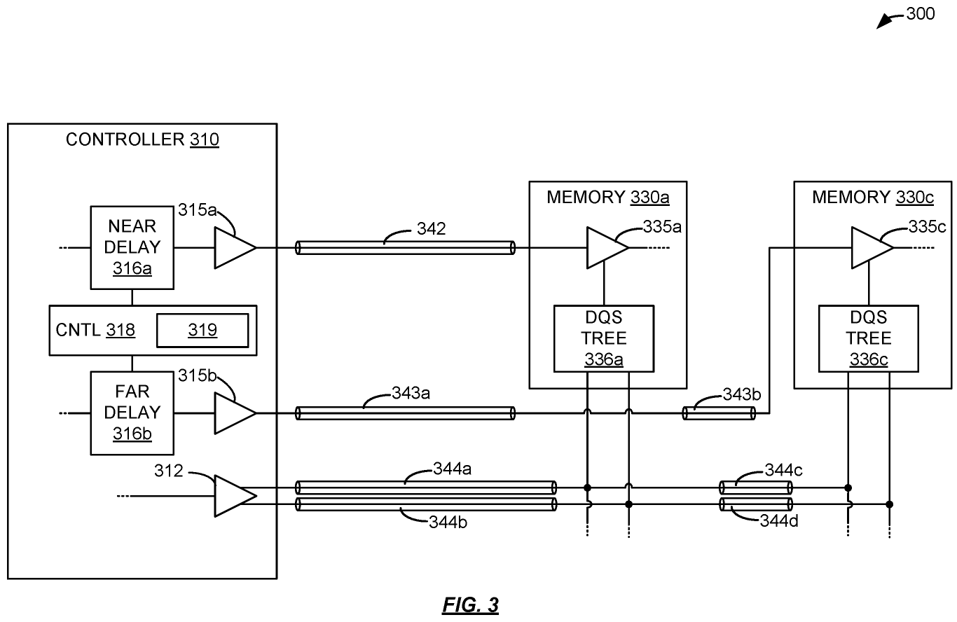

FIG. 3 is a block diagram illustrating write data strobe calibration circuitry. In FIG. 3, memory system 300 comprises controller 310, memory device 330a, memory device 330c, near device data interconnect 342, far device data interconnect 343a-343b, and data strobe interconnect 344a-344d. Controller 310 may be an example of some of the circuitry and write data functionality of controller 110 and memory system 100 illustrated in FIG. 1 and/or of controller 210 and environment 200 illustrated in FIG. 2. Other memory devices may be included in memory system 300 that, for the sake of brevity and clarity, are not shown in FIG. 3.

Controller 310 includes data strobe transmitter 312, near device data transmitter 315a, far device data transmitter 315b, near delay 316a, far delay 316b, and control circuitry 318. Control circuitry 318 includes configuration information 319 (e.g., configuration information in storage such as a register). The differential outputs of data strobe transmitter 312 are operatively coupled to first terminals of data strobe interconnect 344a-344b. The second terminals of data strobe interconnect 344a-344b are operatively coupled to first terminals of data strobe interconnect 344c-344d and the input of data strobe (DQS) tree 336a. Second terminals of data strobe interconnect 344c-344d are operatively coupled to the input of DQS tree 336c. In an embodiment, interconnect 344c-344d represents a difference in propagation time between interconnect 344a-344b from data strobe transmitter 312 to near memory device 330a and interconnect 344a-344d from data strobe transmitter 312 to far memory device 330c.

The output of near device data transmitter 315a is operatively coupled to a first terminal of near device data interconnect 342 and the input of near device data transmitter 315a is operatively coupled to near delay 316a. The output of far device data transmitter 315b is operatively coupled to a first terminal of far device data interconnect 343a-343b and the input of far device data transmitter 315b is operatively coupled to far delay 316b. Near delay 316a is operatively coupled to control circuitry 318 to allow control circuitry 318 to adjust the timing, relative to the data strobe signal transmitted by data strobe transmitter 312, of the data transmitted by near device data transmitter 315a. Far delay 316b is operatively coupled to control circuitry 318 to allow control circuitry 318 to adjust the timing, relative to the data strobe signal transmitted by data strobe transmitter 312, of the data transmitted by far device data transmitter 315b.

Memory device 330a and memory device 330c respectively include receiver (a.k.a., sampler) 335a and receiver 335c. Memory device 330a and memory device 330c respectively include data strobe (DQS) tree 336a and DQS tree 336c. The output of DQS tree 336a is operatively coupled to a timing reference input of receiver 335a to control (e.g., set) the timing that receiver 335a samples its data input. The output of DQS tree 336c is operatively coupled to a timing reference input of receiver 335c to control (e.g., set) the timing that receiver 335c samples its data input.

The data input to receiver 335a is operatively coupled to a second terminal of interconnect 342 to receive, via interconnect 342, data transmitted by near device data transmitter 315a. The data input to receiver 335c is operatively coupled to a second terminal of interconnect 343b to receive, via interconnect 343a-343b, data transmitted by far device data transmitter 315b. In an embodiment, interconnect 343b represents the difference in propagation time between interconnect 342 from near device data transmitter 315a to near memory device 330a and interconnect 343a-343b from far device data transmitter 315b to far memory device 330c.

In an embodiment, control circuitry 318 may, during, for example, an initial calibration period, determine, via a calibration process, the propagation delay (e.g., due to interconnect 342) between the output of near device data transmitter 315a and the data input of receiver 335a. Control circuitry 318 may also, during, for example, the initial calibration period, determine, via the calibration process the propagation delay (e.g., due to interconnect 343a-343b) between the output of far device data transmitter 315b and the data input of receiver 335c. These propagation delays may be determined (e.g., measured) relative to the data strobe signal transmitted by data strobe transmitter 312 via interconnect 344a-344d. Thus, the propagation delay from near device data transmitter 315a to the input of data receiver 335a may be based on the propagation delay of interconnect 344a-344b. Similarly, the propagation delay from far device data transmitter 315b to the input of data receiver 335c may be based on the propagation delay of interconnect 344a-344b and interconnect 344c-344d. These measured propagation delays (or delay differences) may be stored in control circuitry 318 as configuration information 319.

In an embodiment, configuration information 319 is used by control circuitry 318 to control the amount of delay provided by near delay 316a and far delay 316b. The delays provided by near delay 316a and far delay 316b allow controller 310 to transmit different groups of data (e.g., data transmitted by near device data transmitter 315a and far data transmitted by far device data transmitter 315b) at different times relative to the data strobe signal transmitted by data strobe transmitter 312 that accompanies the data transmitted by near device data transmitter 315a and data transmitted by far device data transmitter 315b. Thus, for example, controller 310 may use configuration information 319 to transmit data signals, using near delay 316a and far delay 316b, to near memory device 330a and data signals to far memory device 330c, respectively, with a first delay and a second delay, respectively, that are not equal.

In an embodiment, configuration information 319 is stored by, and received by controller 310 from, a serial presence detect (SPD) device (not shown in FIG. 3). In another embodiment, configuration information 319 is stored by, and received by controller 310 from, a host device or host system (not shown in FIG. 3).

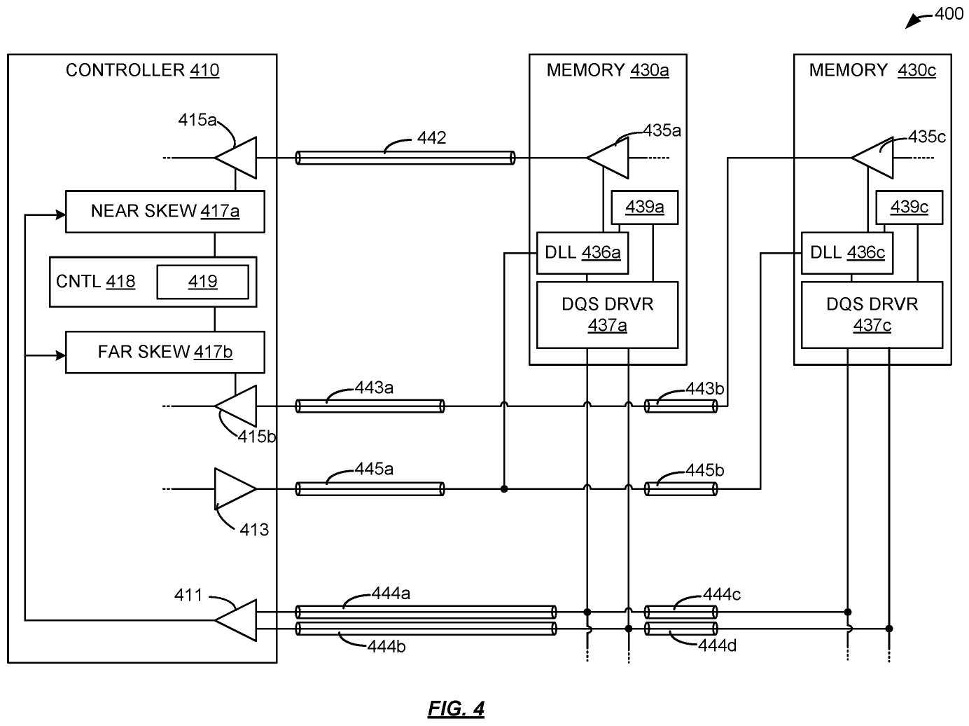

FIG. 4 is a block diagram illustrating read data strobe calibration circuitry. In FIG. 4, memory system 400 comprises controller 410, memory device 430a, memory device 430c, near device data interconnect 442, far device data interconnect 443a-443b, data strobe interconnect 444a-444d, and clock signal interconnect 445a-445b. Controller 410 may be an example of some of the circuitry and read data functionality of controller 110 and memory system 100 illustrated in FIG. 1 and/or of controller 210 and environment 200 illustrated in FIG. 2, and/or of controller 310 and memory system 300 illustrated in FIG. 3. Other memory devices may be included in memory system 400 that, for the sake of brevity and clarity, are not shown in FIG. 4.

Controller 410 includes data strobe receiver 411, near device data receiver 415a, far device data receiver 415b, near skew compensation 417a, far skew compensation 417b, clock signal transmitter 413, and control circuitry 418. Control circuitry 418 includes configuration information 419. The differential inputs of data strobe receiver 411 are operatively coupled to first terminals of data strobe interconnect 444a-444b. The second terminals of data strobe interconnect 444a-444b are operatively coupled to first terminals of data strobe interconnect 444c-444d and the output of data strobe (DQS) transmitter 437a. Second terminals of data strobe interconnect 444c-444d are operatively coupled to the DQS transmitter 437c. In an embodiment, interconnect 444c-444d represents a difference in propagation time between interconnect 444a-444b from data strobe receiver 411 to near memory device 430a and interconnect 444a-444d from data strobe receiver 411 to far memory device 430c.

The input of near device data receiver 415a is operatively coupled to a first terminal of near device data interconnect 442. The timing reference input of near device data receiver 415a is operatively coupled to near skew compensation 417a. The input of far device data receiver 415b is operatively coupled to a first terminal of far device data interconnect 443a-443b. The timing reference input of far device data receiver 415b is operatively coupled to far skew compensation 417b. Near skew compensation 417a is operatively coupled to control circuitry 418 to allow control circuitry 418 to adjust the timing, relative to the data strobe signal received by data strobe receiver 411, of the data received by near device data receiver 415a. Far skew compensation 417b is operatively coupled to control circuitry 418 to allow control circuitry 418 to adjust the timing, relative to the data strobe signal received by data strobe receiver 411, of the data received by far device data receiver 415b.

Memory device 430a and memory device 430c respectively include transmitter (a.k.a., driver) 435a and transmitter 435c. Memory device 430a includes delay locked loop 436a, data strobe transmitter 437a, and configuration information 439a (e.g., configuration information in storage such as a register). Memory device 430c includes delay locked loop 436c, data strobe transmitter 437c, and configuration information 439c. DLL 436a and DLL 436c are operatively coupled, respectively, to the timing reference inputs of transmitter 435a and transmitter 435c. DLL 436a and DLL 436c are operatively coupled, respectively, to the timing reference inputs of DQS transmitter 437a and DQS transmitter 437c. Configuration information 439a is operatively coupled to DQS transmitter 437a and DLL 436a. Configuration information 439c is operatively coupled to DQS transmitter 437c and DLL 436c.

The output of DQS transmitter 437a is operatively coupled to the second terminals of interconnect 444a-444b to, when memory device 430a is configured accordingly by configuration information 439a, provide a timing reference signal to the input of DQS receiver 411, via interconnect 444a-444b, that provides a timing basis for, after skew compensation by skew compensation 417a-417b, receivers 415a-415b, respectively, to sample their respective data inputs. The output of DQS transmitter 437c is operatively coupled to the second terminals of interconnect 444c-444d to, when memory device 430c is configured accordingly by configuration information 439c, provide a timing reference signal to the input of DQS receiver 411, via interconnect 444a-444d, that provides a timing basis for, after skew compensation by skew compensation 417a-417b, receivers 415a-415b, respectively, to sample their respective data inputs.

The data output of near device data transmitter 435a is operatively coupled to a second terminal of interconnect 442 to transmit, via interconnect 442, data to be received by near data receiver 415a. The data output of far device data transmitter 435c is operatively coupled to a second terminal of interconnect 443b to transmit, via interconnect 443a-443b, data to be received by far data receiver 415b. In an embodiment, interconnect 443b represents the difference in propagation time between interconnect 442 from near data receiver 415a to near memory device 430a and interconnect 443a-443b from far data receiver 415b to far memory device 430c.

The output of clock signal transmitter 413 is operatively coupled to a first terminal of clock signal interconnect 445a. The second terminal of clock signal interconnect 445a is operatively coupled to delay locked loop (DLL) 436a of memory device 430a and a first terminal of clock signal interconnect 445b. The second terminal of clock signal interconnect 445b is operatively coupled to DLL 436c of memory device 430c. In an embodiment, interconnect 445b represents the difference in propagation time between clock signal transmitter 413 to near memory device 430a via interconnect 445a and the propagation time between clock signal transmitter 413 to far memory device 430c via interconnect 445a-445b.

In an embodiment, DLL 436a is configured to, based on the clock signal transmitted by clock signal transmitter 413, generate timing reference signals for provision to data transmitter 435a and DQS transmitter 437a. DLL 436c is configured to, based on the clock signal transmitted by clock signal transmitter 413, generate timing reference signals for provision to data transmitter 435c and DQS transmitter 437c. In an embodiment, DLL 436a and DLL 436c are configured to provide timing reference signals that match each other. In other words, DLL 436a and DLL 436c are configured to provide timing reference signals to data transmitter 435a and data transmitter 435c, respectively, such that data transmitter 435a and data transmitter 435c both initiate transitions at substantially the same time. Likewise, DLL 436a and DLL 436c are configured to provide timing reference signals to DQS transmitter 437a and DQS transmitter 437c, respectively, such that, if both DQS transmitter 437a and DQS transmitter 437c were configured to transmit, DQS transmitter 437a and DQS transmitter 437c would both initiate transitions at substantially the same time. In an embodiment, however, only one of DQS transmitter 437a and DQS transmitter 437c are configured by configuration information 439a and configuration information 439c, respectively, to transmit a data strobe signal to data strobe receiver 411.

The data strobe signal transmitted by the configured one of DQS transmitter 437a or DQS transmitter 437c is received by data strobe receiver 411. Data strobe receiver 411 is operatively coupled to near skew compensation 417a and far skew compensation 417b. Near skew compensation 417a is operatively coupled to the timing reference input of near data receiver 415a to control the timing that near data receiver 415a samples the signal presented at the input of near data receiver 415a by interconnect 442. Far skew compensation 417b is operatively coupled to the timing reference input of far data receiver 415b to control the timing that far data receiver 415b samples the signal presented at the input of far data receiver 415b by interconnect 443a.

In an embodiment, control circuitry 418 may, during, for example, an initial calibration period, determine, via a calibration process, a difference in the arrival times of transitions received via near data receiver 415a and data strobe receiver 411. Likewise, control circuitry 418 may, during, for example, the initial calibration period, determine, via a calibration process, a difference in the arrival times of transitions received via far receiver 415b and data strobe receiver 411. These measured differences in arrival times may be stored in control circuitry 418 as configuration information 419.

In an embodiment, configuration information 419 is used by control circuitry 418 to control the amount of delay provided by near skew compensation 417a and far skew compensation 417b. The delays (or skew compensation) provided by near skew compensation 417a and far skew compensation 417b allow controller 410 to receive different groups of data (e.g., data received by data receiver 415a and data received by data receiver 415b) at different times relative to the data strobe signal received by data strobe receiver 411 that accompanies the data received by data receiver 415a and data received by data receiver 415b. Thus, for example, controller 410 may use configuration information 419 to receive data signals, using near skew compensation 417a and far skew compensation 417b, from near memory device 430a and data signals from far memory device 430c, respectively, with a first skew compensation (delay) and a second skew compensation, respectively, that are not equal.

In an embodiment, configuration information 419 is stored by, and received by controller 410 from, a serial presence detect (SPD) device (not shown in FIG. 4). In another embodiment, configuration information 419 is stored by, and received by controller 410 from, a host device or host system (not shown in FIG. 4).

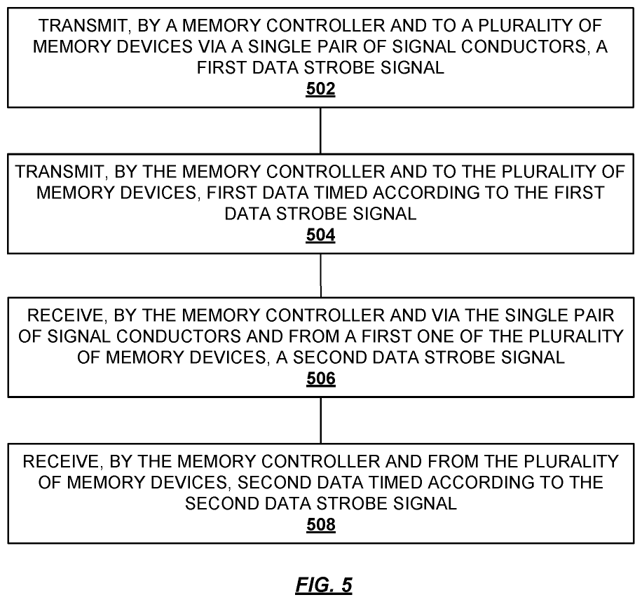

FIG. 5 is a flowchart illustrating a method of sharing data strobe signals. One or more steps illustrated in FIG. 5 may be performed by, for example, memory system 100, environment 200, memory system 300, memory system 400, and/or their components. By a memory controller and to a plurality of memory devices a first data strobe signal is transmitted via a single pair of signal conductors (502). For example, controller 310 (and DQS transmitter 312, in particular) may transmit, to memory device 330a and memory device 330c (and possibly other memory devices) a write data strobe signal via the paired signal conductors of interconnect 344a-344d. By the memory controller and to the plurality of memory devices, first data timed according to the first data strobe signal is transmitted (504). For example, controller 310 may transmit data to memory device 330a via near device data transmitter 315a, and transmit data to memory device 330c via far device data transmitter 315b along with a data strobe signal transmitted by data strobe transmitter 312 that is appropriately aligned with the data strobe signal transmitted by data strobe transmitter 312 by near delay 316a and far delay 316b.

By the memory controller and via the single pair of signal conductors a second data strobe signal is received from a first one of the plurality of memory devices (506). For example, controller 410 (and DQS receiver 411, in particular) may receive, from a single one of memory device 430a and memory device 430c (e.g., memory device 430c) a read data strobe signal via the paired signal conductors of interconnect 444a-444d. By the memory controller and from the plurality of memory devices, second data timed according to the second data strobe signal is received (508). For example, controller 410 may receive data from memory device 430a via near data receiver 415a, and receive data from memory device 430c via far data receiver 415b along with a data strobe signal transmitted by DQS transmitter 437c of memory device 430c where the sampling of the data by near data receiver 415a is appropriately aligned with the received data strobe signal by near skew compensation 417a and the sampling of the data by far data receiver 415b is appropriately aligned with the received data strobe signal by far skew compensation 417b.

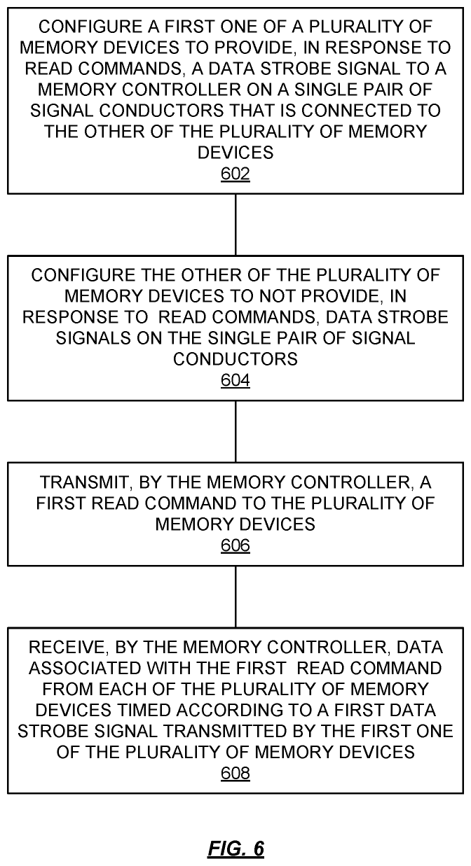

FIG. 6 is a flowchart illustrating a method of providing a read data strobe. One or more steps illustrated in FIG. 6 may be performed by, for example, memory system 100, environment 200, memory system 300, memory system 400, and/or their components. A first one of a plurality of memory devices is configured to provide, in response to read commands, a data strobe signal to a memory controller on a single pair of signal conductors that is connected to the other of the plurality of memory devices (602). For example, memory device 430c may be configured by configuration information 439c to provide to controller 410, in response to read commands, a read data strobe signal on interconnect 444a-444d where both memory device 430a and memory device 430c are connected to interconnect 444a-444d.

Configure the other of the plurality of memory devices to not provide, in response to read commands, data strobe signals on the single pair of signal conductors (604). For example, memory device 430a and any other memory devices connected to interconnect 444a-444d may be configured (e.g., by configuration information 439a) to not provide to controller 410, in response to read commands, a read data strobe signal on interconnect 444a-444d where both memory device 430a and memory device 430c are connected to interconnect 444a-444d. By the memory controller and to the plurality of memory device, a read command is transmitted (606). For example, memory controller 410 may transmit, via a command/address bus, a read command to all of the memory devices (e.g., memory device 430a and memory device 430c) connected to interconnect 444a-444d.

By the memory controller, data associated with the first read command is received from each of the plurality of memory devices timed according to a first data strobe signal transmitted by the first one of the plurality of memory devices (608). For example, controller 410 may receive data from memory device 430a via near data receiver 415a, and receive data from memory device 430c via far device data receiver 415b along with a data strobe signal transmitted by DQS transmitter 437c of memory device 430c where the sampling of the data by near data receiver 415a is appropriately aligned with the received data strobe signal by near skew compensation 417a and the sampling of the data by far data receiver 415b is appropriately aligned with the received data strobe signal by far skew compensation 417b.

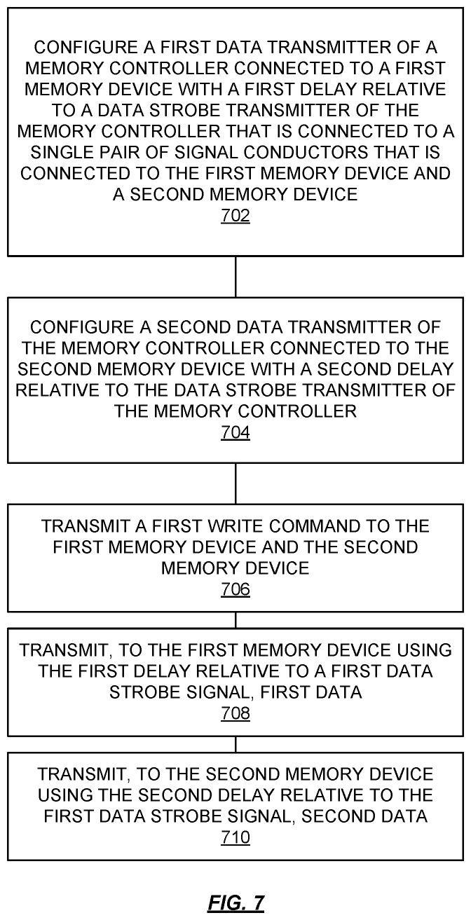

FIG. 7 is a flowchart illustrating a method of transmitting data to multiple memory devices using a common write data strobe. One or more steps illustrated in FIG. 7 may be performed by, for example, memory system 100, environment 200, memory system 300, memory system 400, and/or their components. A first data transmitter of a memory controller connected to a first memory device is configured with a first delay relative to a data strobe transmitter of the memory controller that is connected to a single pair of signal conductors that is connected to the first memory device and a second memory device (702). For example, near device data transmitter 315a of controller 310 may be configured by near delay 316a under the control of control circuitry 318 and configuration information 319 with a first delay relative to the data strobe signal transmitted by data strobe transmitter 312 to memory device 330a and memory device 330c via interconnected 344a-344d.

A second data transmitter of the memory controller connected to the second memory device is configured with a second delay relative to the data strobe transmitter of the memory controller (704). For example, far device data transmitter 315b of controller 310 may be configured by far delay 316b under the control of control circuitry 318 and configuration information 319 with a second delay relative to the data strobe signal transmitted by data strobe transmitter 312 to memory device 330a and memory device 330c via interconnected 344a-344d. A first write command is transmitted to the first memory device and the second memory device (706). For example, controller 310 may transmit a write command to memory device 330a and memory device 330c via a command/address bus.

First data is transmitted to the first memory device using the first delay relative to a first data strobe signal (708). For example, controller 310 and near device data transmitter 315a, in particular, may transmit data to memory device 330a using a delay relative to the data strobe provided by data strobe transmitter 312 that is based on the delay determined by near delay 316a. Second data is transmitted to the second memory device using the second delay relative to the first data strobe signal (710). For example, controller 310 and far device data transmitter 315b, in particular, may transmit data to memory device 330c using a delay relative to the data strobe provided by data strobe transmitter 312 that is based on the delay determined by far delay 316b.

Data strobe (DQS) signals are described and shown herein as using differential signaling and interconnect. It should be understood, however, that this is merely an example configuration. The data strobes described herein (e.g., data strobe (DQS) transmitters 212, 232a-232d, 312, 437a, and 437c, data strobe receivers 211, 231a-231c, and 411, and DQS trees 336a, 336c) and associated interconnect may use a single-ended signaling configuration.

The methods, systems and devices described above may be implemented in computer systems, or stored by computer systems. The methods described above may also be stored on a non-transitory computer readable medium. Devices, circuits, and systems described herein may be implemented using computer-aided design tools available in the art, and embodied by computer-readable files containing software descriptions of such circuits. This includes, but is not limited to one or more elements of memory system 100, environment 200, memory system 300, memory system 400, and their components. These software descriptions may be: behavioral, register transfer, logic component, transistor, and layout geometry-level descriptions. Moreover, the software descriptions may be stored on storage media or communicated by carrier waves.

Data formats in which such descriptions may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email. Note that physical files may be implemented on machine-readable media such as: 4 mm magnetic tape, 8 mm magnetic tape, 3½ inch floppy media, CDs, DVDs, and so on.

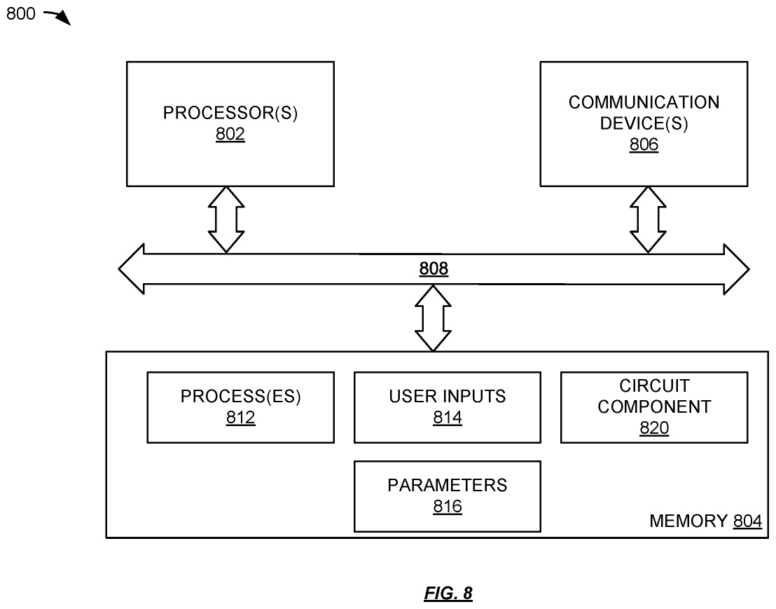

FIG. 8 is a block diagram illustrating one embodiment of a processing system 800 for including, processing, or generating, a representation of a circuit component 820. Processing system 800 includes one or more processors 802, a memory 804, and one or more communications devices 806. Processors 802, memory 804, and communications devices 806 communicate using any suitable type, number, and/or configuration of wired and/or wireless connections 808.

Processors 802 execute instructions of one or more processes 812 stored in a memory 804 to process and/or generate circuit component 820 responsive to user inputs 814 and parameters 816. Processes 812 may be any suitable electronic design automation (EDA) tool or portion thereof used to design, simulate, analyze, and/or verify electronic circuitry and/or generate photomasks for electronic circuitry. Representation 820 includes data that describes all or portions of memory system 100, environment 200, memory system 300, memory system 400, and their components, as shown in the Figures.

Representation 820 may include one or more of behavioral, register transfer, logic component, transistor, and layout geometry-level descriptions. Moreover, representation 820 may be stored on storage media or communicated by carrier waves.

Data formats in which representation 820 may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email

User inputs 814 may comprise input parameters from a keyboard, mouse, voice recognition interface, microphone and speakers, graphical display, touch screen, or other type of user interface device. This user interface may be distributed among multiple interface devices. Parameters 816 may include specifications and/or characteristics that are input to help define representation 820. For example, parameters 816 may include information that defines device types (e.g., NFET, PFET, etc.), topology (e.g., block diagrams, circuit descriptions, schematics, etc.), and/or device descriptions (e.g., device properties, device dimensions, power supply voltages, simulation temperatures, simulation models, etc.).

Memory 804 includes any suitable type, number, and/or configuration of non-transitory computer-readable storage media that stores processes 812, user inputs 814, parameters 816, and circuit component 820.

Communications devices 806 include any suitable type, number, and/or configuration of wired and/or wireless devices that transmit information from processing system 800 to another processing or storage system (not shown) and/or receive information from another processing or storage system (not shown). For example, communications devices 806 may transmit circuit component 820 to another system. Communications devices 806 may receive processes 812, user inputs 814, parameters 816, and/or circuit component 820 and cause processes 812, user inputs 814, parameters 816, and/or circuit component 820 to be stored in memory 804.

Implementations discussed herein include, but are not limited to, the following examples:

Example 1: A memory controller, comprising: a data interface, comprising at least two separate data signals, to communicate data with at least two separate memory devices, respectively; and a data strobe interface to transmit a first data strobe signal providing, to the at least two separate memory devices during write operations, a first timing for the at least two separate data signals and to receive, from a first memory device of the at least two separate memory devices, a second data strobe signal providing, to the memory controller, a second timing for the at least two separate data signals.

Example 2: The memory controller of example 1, further comprising: circuitry to configure the first memory device to provide the second data strobe signal to the memory controller.

Example 3: The memory controller of example 1, wherein the first data strobe signal is transmitted during a write operation.

Example 4: The memory controller of example 2, wherein the second data strobe signal is transmitted during a read operation.

Example 5: The memory controller of example 2, wherein a second memory device of the at least two separate memory devices presents an on-die termination impedance to the second data strobe signal while the first memory device is transmitting the second data strobe signal.

Example 6: The memory controller of example 1, further comprising: circuitry to configure the at least two separate memory devices to calibrate skew between the first data strobe signal and the at least two separate data signals.

Example 7: The memory controller of example 1, wherein the data strobe interface is to communicate the first data strobe signal and the second data strobe signal with the at least two separate memory devices via an H-tree signal routing topology.

Example 8: The memory controller of example 1, wherein the data strobe interface is to communicate the first data strobe signal and the second data strobe signal with the at least two separate memory devices via a star signal routing topology.

Example 9: The memory controller of example 1, further comprising: circuitry to configure an on-die termination impedance of at least two separate memory devices.

Example 10: A memory controller, comprising: a data strobe interface to transmit a first data strobe signal to a plurality of memory devices via a single pair of signal conductors; and a data interface to transmit, to the plurality of memory devices, first data timed according to the first data strobe signal.

Example 11: The memory controller of example 10, wherein the data strobe interface is to receive, via the single pair of signal conductors and from a first memory device of the plurality of memory devices, a second data strobe signal, and the data interface is to receive, from the plurality of memory devices, second data timed according to the second data strobe signal.

Example 12: The memory controller of example 11, further comprising: first circuitry to configure the first memory device of the plurality of memory devices to provide the second data strobe signal to the memory controller via the single pair of signal conductors.

Example 13: The memory controller of example 12, further comprising: second circuitry to configure an on-die termination impedance of the plurality of memory devices.

Example 14: The memory controller of example 13, wherein a second memory device of the plurality of memory devices presents the on-die termination impedance to the single pair of signal conductors while the first memory device of the plurality of memory devices is transmitting the second data strobe signal.

Example 15: The memory controller of example 14, further comprising: third circuitry to configure the plurality of memory devices to calibrate skew between the first data strobe signal and the first data.

Example 16: A method, comprising: transmitting, by a memory controller and to a plurality of memory devices via a single pair of signal conductors, a first data strobe signal; and transmitting, by the memory controller and to the plurality of memory devices, first data timed according to the first data strobe signal.

Example 17: The method of example 16, further comprising: receiving, by the memory controller and via the single pair of signal conductors and from a first memory device of the plurality of memory devices, a second data strobe signal; and receiving, by the memory controller from the plurality of memory devices, second data timed according to the second data strobe signal.

Example 18: The method of example 17, further comprising: configuring the first memory device of the plurality of memory devices to provide the second data strobe signal to the memory controller via the single pair of signal conductors.

Example 19: The method of example 18, further comprising: configuring an on-die termination impedance that the plurality of memory devices are to present to the single pair of signal conductors.

Example 20: The method of example 19, wherein a second memory device of the plurality of memory devices presents the on-die termination impedance to the single pair of signal conductors while the first memory device of the plurality of memory devices is transmitting the second data strobe signal.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A memory controller, comprising:
a data interface, comprising at least two separate data signals, to communicate data with at least two separate memory devices, respectively; and
a data strobe interface to transmit a first data strobe signal providing, to the at least two separate memory devices during write operations, a first timing for the at least two separate data signals and to receive, from a first memory device of the at least two separate memory devices, a second data strobe signal providing, to the memory controller, a second timing for the at least two separate data signals.

2. The memory controller of claim 1, further comprising:
circuitry to configure the first memory device to provide the second data strobe signal to the memory controller.

3. The memory controller of claim 1, wherein the first data strobe signal is transmitted during a write operation.

4. The memory controller of claim 2, wherein the second data strobe signal is transmitted during a read operation.

5. The memory controller of claim 2, wherein a second memory device of the at least two separate memory devices presents an on-die termination impedance to the second data strobe signal while the first memory device is transmitting the second data strobe signal.

6. The memory controller of claim 1, further comprising:
circuitry to configure the at least two separate memory devices to calibrate skew between the first data strobe signal and the at least two separate data signals.

7. The memory controller of claim 1, wherein the data strobe interface is to communicate the first data strobe signal and the second data strobe signal with the at least two separate memory devices via an H-tree signal routing topology.

8. The memory controller of claim 1, wherein the data strobe interface is to communicate the first data strobe signal and the second data strobe signal with the at least two separate memory devices via a star signal routing topology.

9. The memory controller of claim 1, further comprising:
circuitry to configure an on-die termination impedance of at least two separate memory devices.

10. A memory controller, comprising:
a data strobe interface to transmit a first data strobe signal to a plurality of memory devices via a single pair of signal conductors; and
a data interface to transmit, to the plurality of memory devices, first data timed according to the first data strobe signal.

11. The memory controller of claim 10, wherein the data strobe interface is to receive, via the single pair of signal conductors and from a first memory device of the plurality of memory devices, a second data strobe signal, and the data interface is to receive, from the plurality of memory devices, second data timed according to the second data strobe signal.

12. The memory controller of claim 11, further comprising:
first circuitry to configure the first memory device of the plurality of memory devices to provide the second data strobe signal to the memory controller via the single pair of signal conductors.

13. The memory controller of claim 12, further comprising:
second circuitry to configure an on-die termination impedance of the plurality of memory devices.

14. The memory controller of claim 13, wherein a second memory device of the plurality of memory devices presents the on-die termination impedance to the single pair of signal conductors while the first memory device of the plurality of memory devices is transmitting the second data strobe signal.

15. The memory controller of claim 14, further comprising:
third circuitry to configure the plurality of memory devices to calibrate skew between the first data strobe signal and the first data.

16. A method, comprising:
transmitting, by a memory controller and to a plurality of memory devices via a single pair of signal conductors, a first data strobe signal; and
transmitting, by the memory controller and to the plurality of memory devices, first data timed according to the first data strobe signal.

17. The method of claim 16, further comprising:
receiving, by the memory controller and via the single pair of signal conductors and from a first memory device of the plurality of memory devices, a second data strobe signal; and
receiving, by the memory controller from the plurality of memory devices, second data timed according to the second data strobe signal.

18. The method of claim 17, further comprising:
configuring the first memory device of the plurality of memory devices to provide the second data strobe signal to the memory controller via the single pair of signal conductors.

19. The method of claim 18, further comprising:
configuring an on-die termination impedance that the plurality of memory devices are to present to the single pair of signal conductors.

20. The method of claim 19, wherein a second memory device of the plurality of memory devices presents the on-die termination impedance to the single pair of signal conductors while the first memory device of the plurality of memory devices is transmitting the second data strobe signal.
